(19) United States
(12) Patent Application Publication
(10) Pub. No.: US 2023/0377956 A1
(43) Pub. Date: Nov. 23, 2023

(54) METHOD OF FORMING AN INTERCONECT STRUCTURE OF A SEMICONDUCTOR DEVICE

(71) Applicant: Taiwan Semiconductor Manufacturing Company, Ltd., Hsinchu (TW)

(72) Inventors: Chien-Han Chen, Nantou (TW); Shih-Yu Chang, Yunlin (TW); Chien-Chih Chiu, Kinying City (TW); Huang-Ming Chen, Hsinchu (TW)

(73) Assignee: Taiwan Semiconductor Manufacturing Company, Ltd., Hsinchu (TW)

(21) Appl. No.: 17/664,466

(22) Filed: May 23, 2022

(51) Int. Cl. H01L 21/768; H01L 23/522; H01L 21/311; H01L 21/027

(52) U.S. Cl. CPC H01L 21/76829; H01L 21/76816; H01L 23/5226; H01L 21/311; H01L 21/0273; H01L 21/76841

(57) ABSTRACT

A method of forming a semiconductor device structure is disclosed. First and second etch stop layers are formed overlying a semiconductor structure having a conductive feature formed therein. A dielectric layer is formed overlying the second etch stop layer, and a hard mask, that comprises a tungsten-based material, is formed overlying the dielectric layer, and patterned. A resist layer is formed over the patterned hard mask. Using the patterned resist layer as a mask, a first etching process is performed to form a via opening that extends partially through the dielectric layer. Using the patterned hard mask as an etch mask, a second etching process (e.g., dry etching process) is performed to extend the via opening through the second etch stop layer, and a third etching process (e.g., wet etching process) is performed to extend the via opening through the first etch stop layer to reach the conductive feature.

### BACKGROUND

The fabrication of integrated circuits can be broadly separated into two main sections, front-end-of-the-line (FEOL) fabrication and back-end-of-the-line (BEOL) fabrication. FEOL fabrication includes the formation of devices (e.g., transistors, capacitors, resistors, etc.) within a semiconductor substrate. BEOL fabrication includes the formation of one or more metal interconnect layers comprised within one or more insulating dielectric layers disposed above the semiconductor substrate. The metal interconnect layers of the BEOL electrically connect individual devices of the FEOL to external pins of an integrated chip.

Technological advances in IC materials and design have produced generations of ICs. Each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

As feature sizes continue to decrease, fabrication processes continue to become more complex, especially with decreasing lithographic feature sizes, decreasing critical dimensions of features and decreasing pitch between features. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method of forming an interconnect structure of a semiconductor device structure in accordance with some embodiments.

FIGS. 2A-2N are cross-sectional views of various stages of a process for forming an interconnect structure of a semiconductor device structure in accordance with some embodiments.

FIG. 3 is a cross-sectional view that illustrates different back-end-of-line interconnect layers of an integrated circuit architecture where interconnect structures fabricated in accordance with FIGS. 1 and 2A-2N may be integrated in accordance with some embodiments.

### DETAILED DESCRIPTION

The present disclosure relates generally to semiconductor structures, and more particularly, to interconnect structures and methods of forming interconnect structures.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Further, spatially relative terms, such as “beneath,” “below,” “under,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

During a BEOL fabrication process, various dielectric layers and interconnect structures are formed overlying a semiconductor substrate that was fabricated during a FEOL fabrication process. With many modern BEOL fabrication processes, there is a need to form interconnect structures having very small critical dimensions so that they can be electrically connected to various device elements that were formed in and/or on the semiconductor substrate during a FEOL fabrication process. During the BEOL fabrication process, various etching steps are performed, and in some cases, due to the small critical dimensions involved, an under etching problem can occur during the process of forming via openings in which conductive vias are ultimately formed. It would be desirable to reduce or eliminate such under etching problems without making the fabrication sequence used to form the via openings unnecessarily complex.

To address these issues, fabrication techniques are provided that utilize a hard mask that comprises a tungsten-based material when forming via openings during a BEOL fabrication process. When a hard mask that comprises a tungsten-based material is used during the process of forming the via openings, etching by-products (e.g., tungsten fluoride (WFₓ)) are produced that have a lower boiling point, and under-etching effects can be reduced. Due to the lower boiling point etching by-products do not tend to accumulate in and block etching of the via openings that are being etched. As a result, under etching of the via openings can be greatly reduced or eliminated. In some non-limiting embodiments, the disclosed techniques can be used to fabricate vias for interconnect structures having small critical dimensions, such as those in a metal one (M1) interconnect layer that are used to provide a connection to conductive features that part of a metal zero (M0) layer (e.g., that are used to provide an electrical connection to device elements formed in a semiconductor substrate that was fabricated during a FEOL fabrication process).

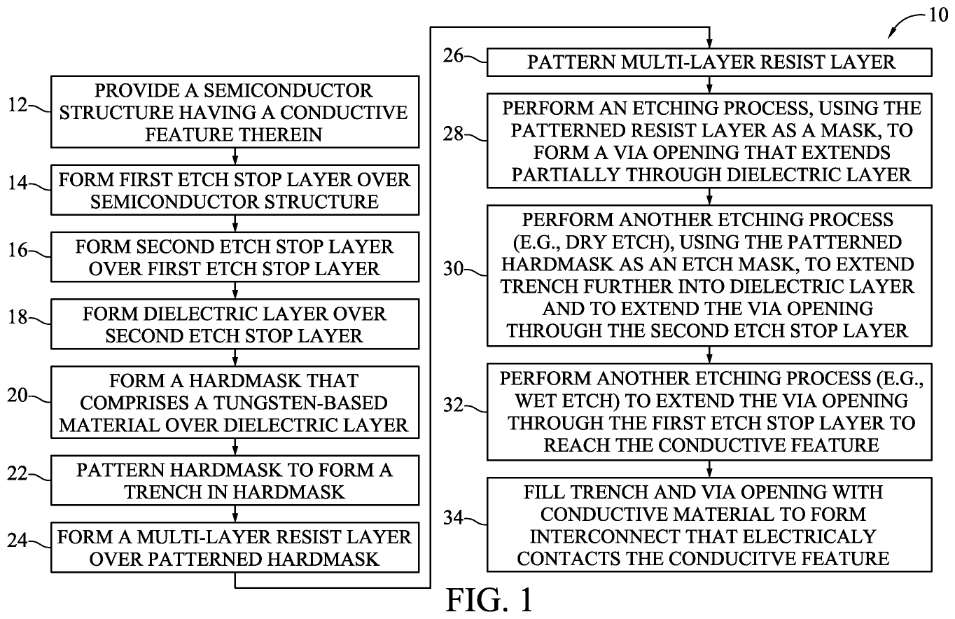

FIG. 1 is a flowchart of a method 10 of forming an interconnect structure of a semiconductor device structure in accordance with some embodiments. It is understood that additional steps can be provided before, during, and after the method 10, and some of the steps described can be replaced or eliminated for other embodiments of the method 10.

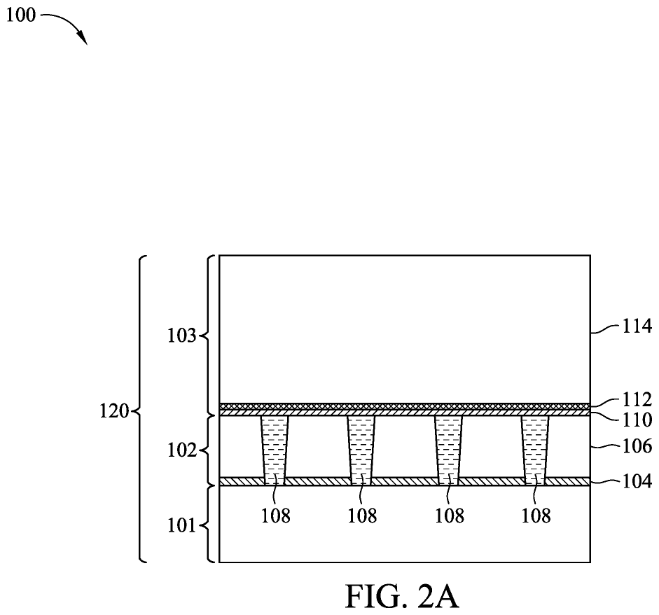

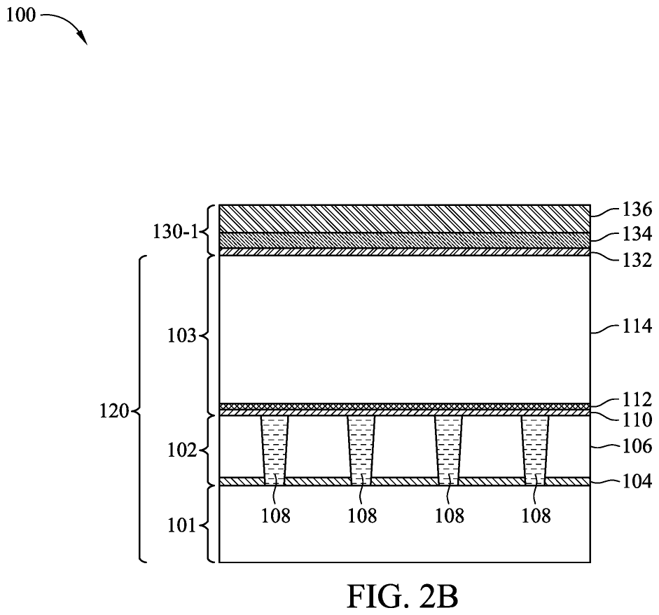

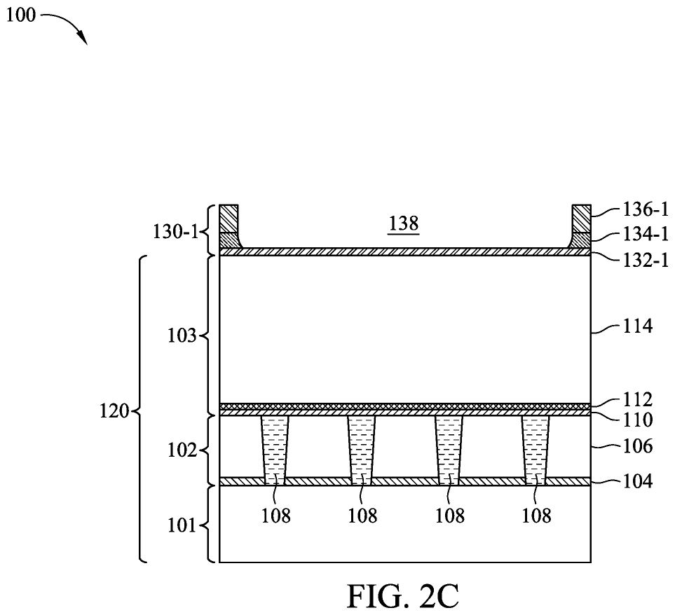

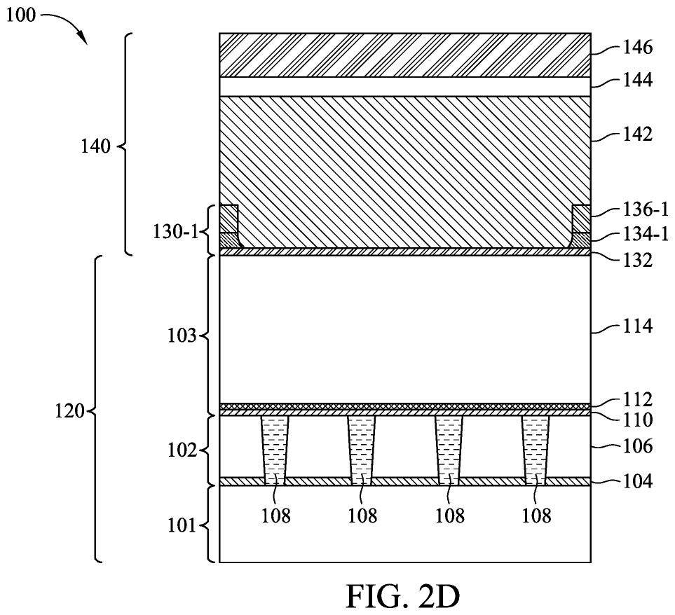

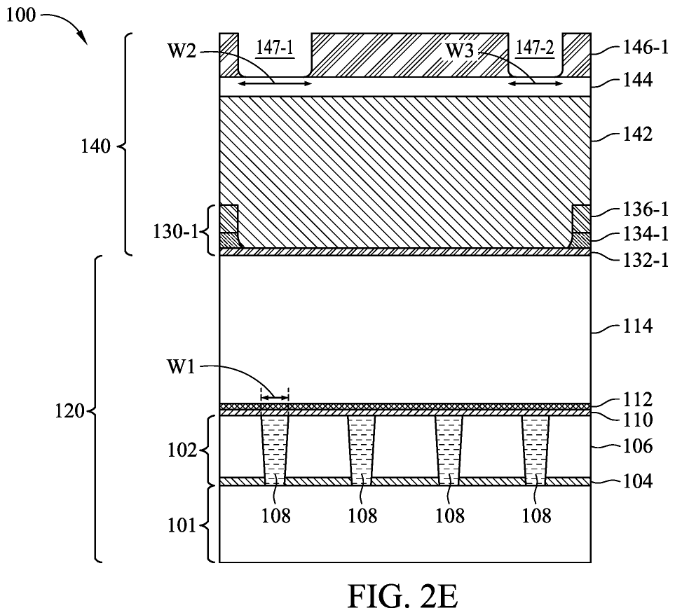

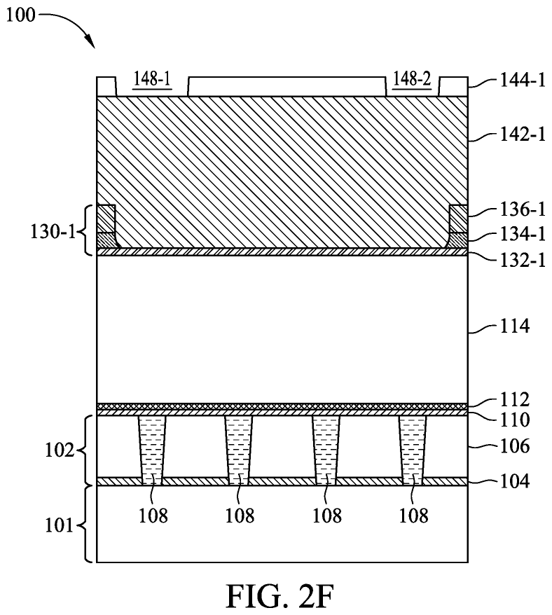

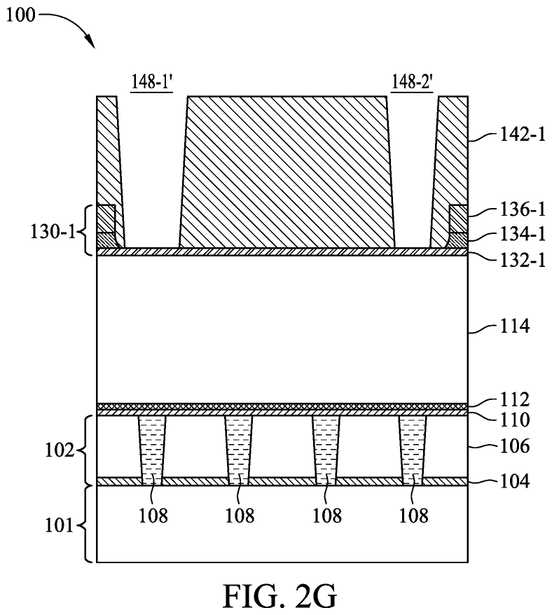

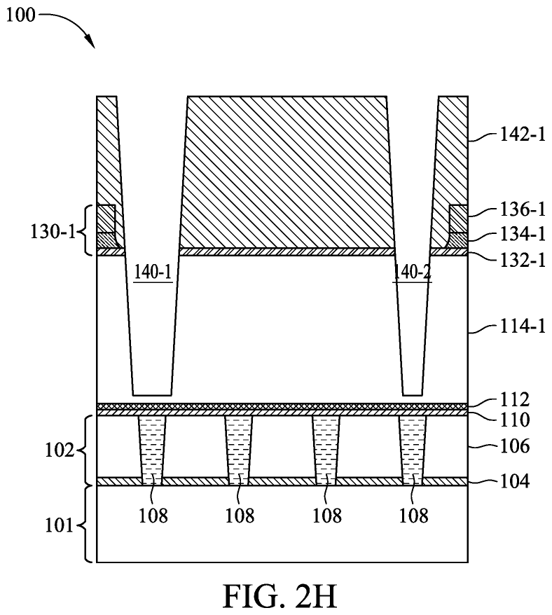

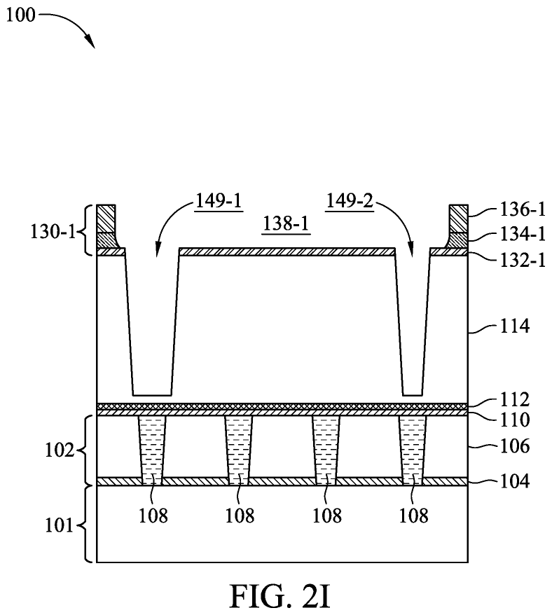

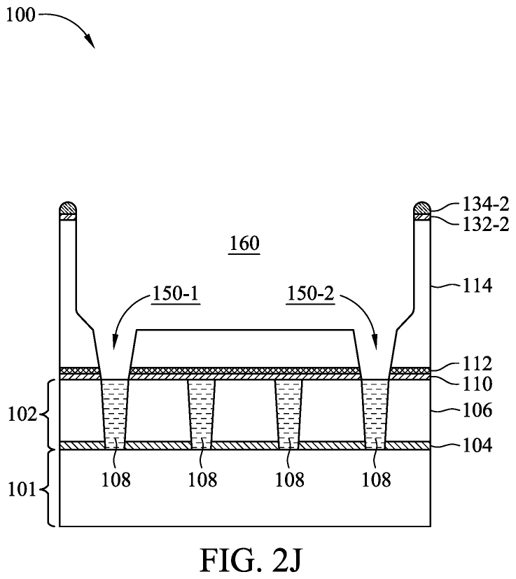

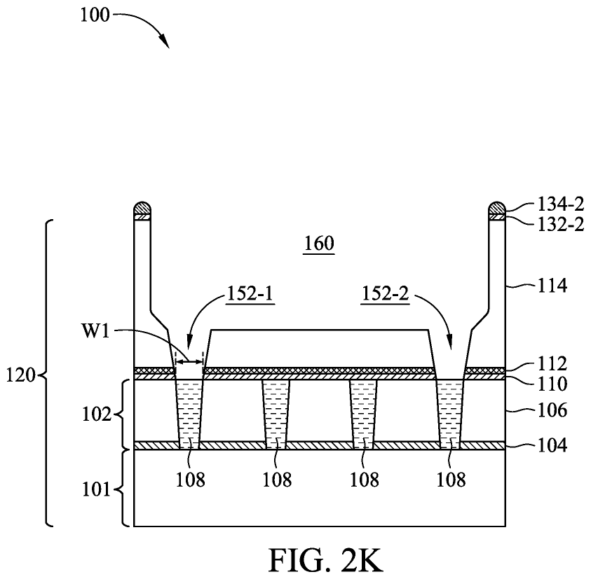

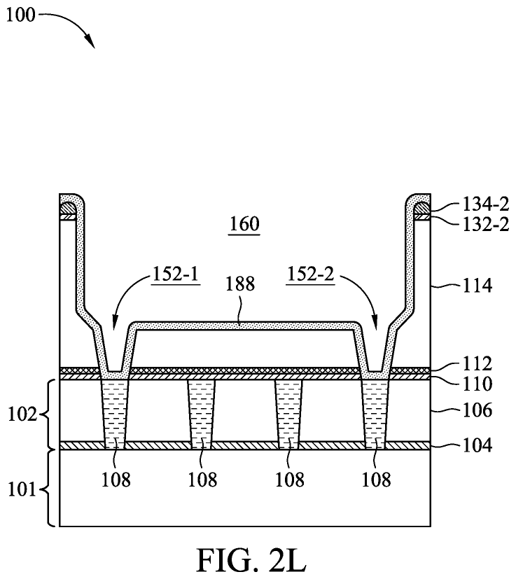

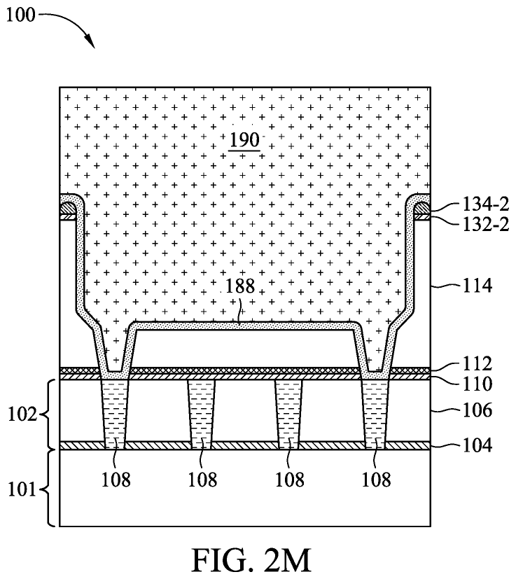

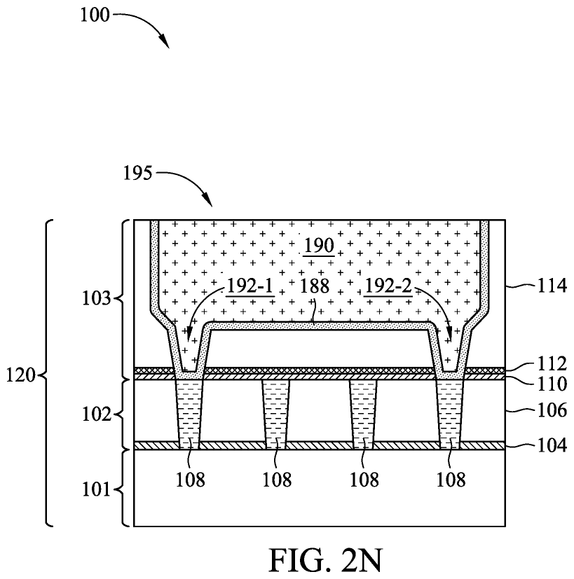

The method 10 begins at step 12 in which a semiconductor structure can be provided, created, fabricated, or otherwise formed. One non-limiting example of such a semiconductor structure is described below with reference to FIG. 2A. The semiconductor structure has one or more conductive features formed therein. The semiconductor structure can vary depending on the implementation. The semiconductor structure can include any number of materials layers formed over a semiconductor substrate. The semiconductor substrate can include any number of conductive features and device elements formed in and/or over the semiconductor substrate. Conductive features can include, for example, plugs, interconnects, wiring lines, etc. Device elements can include, for example, transistors, diodes, capacitors, etc. For example, the transistors may be metal oxide semiconductor field effect transistors (MOSFETs), complementary metal oxide semiconductor (CMOS) transistors, bipolar junction transistors (BJT), high-voltage transistors, high-frequency transistors, p-channel field effect transistors (PFETs) and/or n channel field effect transistors (NFETs), etc. In some embodiments, the transistors may be planar FETs, multi-gate FET devices, FinFET devices, gate-all-around (GAA) FET device (also referred to as surround-gate FET devices), and/or Nanosheet FET devices, as will be described in greater detail below.

At step 14, a first etch stop layer is formed overlying the semiconductor structure. The method 10 continues with step 16 in which a second etch stop layer is formed overlying the first etch stop layer. The method 10 continues with step 18 in which a dielectric layer is formed overlying the second etch stop layer.

At steps 20 through 34 the interconnect structure is formed in the dielectric layer. The method 10 continues with step 20 in which a hard mask is formed overlying the dielectric layer. The hard mask comprises a tungsten-based material, such as, tungsten carbide (WC) or tungsten nitride (WN). The method 10 continues with step 22 in which a trench is patterned in the hard mask to create a patterned hard mask.

The method 10 continues with step 24 in which a multi-layer resist layer is formed over the patterned hard mask. The multi-layer resist layer comprises an upper layer, a middle layer, and a bottom layer. The method 10 continues with step 26 in which a first set of etching processes is performed to pattern the multi-layer resist layer. This forms a patterned bottom layer. The method 10 continues with step 28 in which another etching process is performed, using the patterned bottom layer as a mask, to form a via opening that extends partially through the dielectric layer.

The method 10 continues with step 30 in which a dry etching process is performed, using the patterned hard mask as an etch mask, to extend the trench further into the dielectric layer and to extend the via opening through the second etch stop layer. The method 10 continues with step 32 in which a wet etching process is performed to extend the via opening through the first etch stop layer to reach the conductive feature. The method 10 continues with step 34 in which the via opening and the trench are filled with a conductive material to form the interconnect structure in the dielectric layer. The interconnect structure electrically contacts one or more of the conductive features.

In accordance with the method 10, using a hard mask that comprises a tungsten-based material can be advantageous in comparison to using other conventional types of hard masks, such as, metal nitride hard masks. One reason is because the etching by-products, that are generated during various etching steps, do not tend to block via openings that are being etched, and therefore, under-etching can be reduced. To explain further, when the trench is patterned in the hard mask (at step 22), or when the patterned hard mask is used as an etch mask during the dry etching process (at step 30), etching by-products are produced that have a relatively low boiling point (e.g., relatively high volatility or tendency to vaporize) in comparison to the by-products that are produced when the hard mask material is made of other types of materials that are often used as hard mask layer, such as metal nitrides like TiN. To explain further, when etching a dielectric material, a fluoro-containing etching gas (e.g., CF₄, C₄F₈, etc.) is usually applied. Reactions between this etching gas and the hard mask material can result in fluorinated etching by-products being generated. Depending on the material used for the hard mask, different fluorinated etching by-products can result that have a range of different boiling points (e.g., some etching by products are less volatile while others are more volatile.

For example, when a TiN hardmask is used, a titanium fluoride (TiFₓ) by-product is generated. The titanium fluoride (TiFₓ) by-product is metallic and has relatively high boiling point (e.g., has less tendency to vaporize and is less volatile). The titanium fluoride (TiFₓ) by-product can accumulate in and block the via openings, which in turn, can result in under-etching of the via openings. This is especially true when the via openings are for vias having small critical dimensions. As critical dimensions of the via become smaller, these titanium fluoride (TiFₓ) by-products can negatively impact (e.g., block or prevent) etching of the via openings. As a result of this blockage, under-etching of the via openings can occur. For example, it has been observed that when other types of hard masks are utilized, such as metal nitride hard masks (e.g., a titanium nitride (TiN) hard mask or the like), under-etching of via openings occurs.

These etching by-products can be deposited and accumulate in the small and narrow via openings and/or along the trench, which can later cause under etching problems to occur during subsequent etching steps during the process of forming the via openings. If under etching is left unaddressed, the vias that are eventually formed in the under etched via openings have degraded electrical contact with the conductive feature that they contact. For example, in some cases, this can result in a via that exhibits poor quality of contact with the conductive feature (e.g., a via that has poor performance). In an extreme case, this can result in a via that does not contact the conductive feature at all (e.g., a via that is inoperable). In either case, if under etching is not addressed, the quality of the via is negatively impacted.

By contrast, when a hard mask that comprises a tungsten-based material is used (as in method 10), under-etching issues can be reduced in comparison to other approaches that use different hard mask materials. When a hard mask that comprises a tungsten-based material is used, the etching by-products have a lower boiling point, and under-etching effects can be reduced. To explain further, when a hard mask that comprises a tungsten-based material is used, tungsten fluoride (WFₓ) etching by-products are produced that have a lower boiling point than the etching by-products that result when another material, like titanium nitride (TiN), is used as the hard mask. Due to the lower boiling point of tungsten fluoride, etching by-products do not tend to accumulate in the via openings. As a result, under etching of the via openings can be greatly reduced or eliminated.

One option for addressing under etching would be to perform additional etching steps, but this would require additional complexity to the fabrication sequence in order to extend via opening to reach the conductive feature. In addition, additional etch stop layers would be required, which would add even more complexity to the overall fabrication sequence. As such, another advantage of method 10 is that because under etching is no longer a concern, the number of etching steps that are needed can be reduced. To explain further, in method 10, once the initial via opening is formed (at step 28), only two etching steps 30, 32 (e.g., a dry etch step at 30 followed by a wet etch step at 32) are performed to extend the via opening to reach the conductive feature. As such, the number of etch stop layers that are needed in method 10 can be reduced in comparison to other approaches where under etching is a concern, which can further simplify the over fabrication sequence used to form the interconnect.

The discussion that follows illustrates embodiments of an interconnect structure 195 of a semiconductor device structure that can be fabricated in accordance with the method 10 of FIG. 1.

FIGS. 2A-2N are cross-sectional views of various stages of a process for forming an interconnect structure 195 of a semiconductor device structure 100 in accordance with some embodiments. FIG. 2A illustrates a semiconductor structure 120 of the semiconductor device structure 100 in accordance with some embodiments. An interconnect structure (not shown in FIG. 2A) may be provided within the semiconductor structure 120. FIGS. 2B-2N show various processing steps involved in a method for fabricating the interconnect structure within a material layer 103 of the semiconductor structure 120. The interconnect structure 195 is illustrated in FIG. 2N.

As shown in FIG. 2A, in accordance with some embodiments, the semiconductor structure 120 may include front-end-of-line (FEOL) structures and back-end-of-line (BEOL) structures. In accordance with some non-limiting embodiments, the FEOL structures can include a semiconductor substrate 101, and the BEOL structure can include first material layers 102 and second material layers 103. The first material layers 102 have a number of conductive features 108 formed therein. The second material layers 103 are layers in which an interconnect structure (not shown) will be fabricated as part of an integrated circuit fabrication process. As shown in FIG. 2N, vias of the interconnect structure 195 may contact one or more of the conductive features 108. In some non-limiting embodiments, the interconnect structure has a dual damascene architecture, but it should be appreciated that the disclosed embodiments can also be used to provide other alternative interconnect structures including, but not limited to, interconnect structures having a single damascene architecture. In some non-limiting embodiments, the first material layers 102 and the conductive features 108 formed therein that may be part of metal zero (M0) interconnect layer of a BEOL architecture, and the second material layers 103 and the interconnect structure that will be formed therein can be part of metal one (M1) interconnect layer of a BEOL architecture. However, it should be appreciated that in other embodiments, the first material layers 102 and the second material layers 103 can be implemented at other metal layers of a BEOL architecture.

Although not illustrated in FIG. 2A, it should be noted that the semiconductor substrate 101 may include various features that are not illustrated for sake of clarity and simplicity. In this regard, the semiconductor substrate 101 may include one or more dielectric layers having multiple conductive features formed therein that are electrically connected to device elements formed in the semiconductor substrate 101. The dielectric layer covers device elements formed in and/or over the semiconductor substrate 101. In some embodiments, the conductive features can be made of or include copper (Cu), aluminum (Al), tungsten (W), titanium (Ti), cobalt (Co), nickel (Ni), gold (Au), platinum (Pt), one or more other suitable materials, or a combination thereof. Various processes, including deposition, etching, planarization, or the like, may be used to form the conductive features (not shown) in the dielectric layer of the semiconductor substrate 101.

In some embodiments, the semiconductor substrate 101 is a bulk semiconductor substrate, such as a semiconductor wafer. For example, the semiconductor substrate is a silicon wafer. The semiconductor substrate includes silicon or another elementary semiconductor material such as germanium. In some other embodiments, the semiconductor substrate includes a compound semiconductor. The compound semiconductor includes gallium arsenide, silicon carbide, indium arsenide, indium phosphide, another suitable material, or a combination thereof. In some embodiments, the semiconductor substrate 101 is a semiconductor-on-insulator (SOI) substrate. The SOI substrate may be fabricated by using a separation by implantation of oxygen (SIMOX) process, a wafer bonding process, another applicable method, or a combination thereof.

In some embodiments, parts of or all of the semiconductor substrate 101 in FIG. 2A are fabricated by a semiconductor manufacturing process flow such as a complementary metal-oxide-semiconductor (CMOS) technology process flow, and thus some processes are only briefly described herein. Furthermore, the semiconductor substrate 101 includes various devices and features, such as additional transistors, bipolar junction transistors, resistors, capacitors, diodes, and fuses, but is simplified for a better understanding of the embodiments of the present disclosure.

In some embodiments, the semiconductor substrate 101 in FIG. 2A is an intermediate structure fabricated during manufacturing of an integrated circuit, or a portion thereof. In some embodiments, various device elements are formed in and/or over the semiconductor substrate 101. The device elements are not shown in figures for the purpose of simplicity and clarity. Examples of the various device elements include transistors, diodes, another suitable element, or a combination thereof. For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel field effect transistors (PFETs) and/or n channel field effect transistors (NFETs), etc. In some embodiments, the transistors may be planar FETs, multi-gate FET devices, FinFET devices, gate-all-around (GAA) FET device (also referred to as surround-gate FET devices), and/or Nanosheet FET devices. Multi-gate FET devices include those transistors whose gate structures are formed on at least two-sides of a channel region. These multi-gate devices may include a p-type metal-oxide-semiconductor device or an n-type metal-oxide-semiconductor multi-gate device. Examples of multi-gate FET devices can include, for example, double-gate FET devices, triple-gate FET devices, omega-gate FET devices. A FinFET device is a field effect transistor with fin-like channels. A GAA FET device includes any device that has its gate structure, or portion thereof, formed on 4-sides of a channel region (e.g., surrounding a portion of a channel region). A nanosheet FET device includes any device that has channel regions in the form of nanosheets, where the term “nanosheet” designates any material portion with nanoscale, or even microscale dimensions, and having an elongate shape, regardless of the cross-sectional shape of this portion. Thus, this term designates both circular and substantially circular cross-section elongate material portions, e.g., nanowires, and beam or bar-shaped material portions including for example a cylindrical or substantially rectangular cross-section.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, the semiconductor substrate is an un-doped substrate. However, in some other embodiments, the semiconductor substrate is a doped substrate such as a P-type substrate or an N-type substrate. In some embodiments, the semiconductor substrate includes various doped regions (not shown) depending on the design requirements of the semiconductor device. The doped regions include, for example, p-type wells and/or n-type wells. In some embodiments, the doped regions are doped with p-type dopants. For example, the doped regions are doped with boron or BF₂. In some embodiments, the doped regions are doped with n-type dopants. For example, the doped regions are doped with phosphor or arsenic. In some embodiments, some of the doped regions are p-type doped, and the other doped regions are n-type doped.

In some embodiments, isolation features (not shown) are formed in the semiconductor substrate 101. The isolation features are used to define active regions and electrically isolate various device elements formed in and/or over the semiconductor substrate 101 in the active regions. In some embodiments, the isolation features include shallow trench isolation (STI) features, local oxidation of silicon (LOCOS) features, other suitable isolation features, or a combination thereof.

Material layer 102 includes an etch stop layer 104 and a dielectric layer 106 having a number of conductive features 108. It should be appreciated that the material layer 102 in accordance with embodiments of the present disclosure is not limited to these layers and conductive features, but rather, that the layers and conductive features are shown to illustrate one non-limiting embodiment. For example, the material layer 102 may include more or less layers. For instance, in some other embodiments, the material layer 102 includes one or more additional layers positioned between the etch stop layer 104 and the substrate 101. In some other embodiments, the material layer 102 includes one or more additional layers positioned between the etch stop layer 112 and the dielectric layer 106. In some other embodiments, the material layer 102 includes one or more additional layers positioned above dielectric layer 106 and the conductive features 108 formed therein (e.g., one or more additional layers positioned under the etch stop layer 110). In some other embodiments, the material layer 102 merely includes the etch stop layer 104 and/or the dielectric layer 106.

As shown in FIG. 2A, material layer 102 can include an etch stop layer 104 that is formed over the semiconductor substrate 101 along with a dielectric layer 106 is deposited over the etch stop layer 104. Embodiments of the etch stop layer 104 will be described below with reference to first etch stop layer 110. The dielectric layer 106 may serve as an ILD or IMD layer of an interconnection structure. Although FIG. 2A shows that the dielectric layer 106 is a single layer, embodiments of the disclosure are not limited thereto. In some other embodiments, the dielectric layer 106 is a multi-layer structure including dielectric sub-layers (not shown).

In some embodiments, the dielectric layer 106 is made of or includes a low dielectric constant (low-k) material, an extreme low-k (ELK) material, silicon oxide, silicon oxynitride, borosilicate glass (BSG), phosphoric silicate glass (PSG), borophosphosilicate glass (BPSG), fluorinated silicate glass (FSG), a porous dielectric material, one or more other suitable materials, or a combination thereof. In some embodiments, the dielectric layer 106 includes a low-k dielectric material or ELK material. The low-k or ELK material may have a dielectric constant that is less than that of standard silicon dioxide. For example, the low-k material may have a dielectric constant in a range from about 1.5 to about 3.5. The ELK material may have a dielectric constant, which is less than about 2.5 or in a range from about 1.5 to about 2.5. Using a low-k or ELK material as the dielectric layer 106 is helpful for reducing resistance capacitance (RC) delay time. A wide variety of low-k or ELK materials may be used for forming the dielectric layer 106. In some embodiments, the low-k dielectric material includes fluorine-doped silicon dioxide, carbon-doped silicon dioxide, porous silicon dioxide, porous carbon-doped silicon dioxide, spin-on organic polymeric dielectric, spin-on silicone based polymeric dielectric, polyimides, aromatic polymers, fluorine-doped amorphous carbon, vapor-deposited parylene, another suitable material, or a combination thereof.

In some embodiments, the dielectric layer 106 is deposited using a chemical vapor deposition (CVD) process, an atomic layer deposition (ALD) process, a spin-on process, a spray coating process, one or more other applicable processes, or a combination thereof.

Although not illustrated in FIG. 2A, in some embodiments, an anti-reflective coating layer may be deposited over the dielectric layer 114. The anti-reflective coating layer may be made of silicon oxycarbide, another suitable material, or a combination thereof. In some embodiments, the anti-reflective coating layer is a nitrogen-free anti-reflective coating (NFARC) layer.

Multiple conductive features 108 may be formed in the dielectric layer 106. The conductive features 108 may be conductive lines or other suitable conductive features. At least some of the conductive features 108 may be electrically connected to device elements within the semiconductor substrate 101. For example, the conductive features 108 may be electrically connected to the device elements through the conductive features (not shown) in the dielectric layer of the semiconductor substrate 101.

Although FIG. 2A shows that each of the conductive features 108 is a single layer, embodiments of the disclosure are not limited thereto. Although not shown, depending on the embodiment, the conductive features 108 may be single or dual damascene structures. In some embodiments, the conductive features are made of or include copper (Cu), aluminum (Al), tungsten (W), titanium (Ti), cobalt (Co), nickel (Ni), gold (Au), platinum (Pt), one or more other suitable materials, or a combination thereof. The conductive features 108 may be a multi-layer structure including conductive sub-layers. For example, the conductive sub-layers include a diffusion barrier layer, a seed layer, a metal-filling layer, one or more other suitable layers, or a combination thereof. The conductive sub-layers are not shown in figures for the purpose of simplicity and clarity. Various processes, including deposition, etching, planarization, or the like, may be used to form the conductive features 108 in the dielectric layer 106.

Conductive features 108 are shown in FIG. 2A as an example. It should be noted that the dimensions of the conductive features 108 shown in FIG. 2A are only an example and not a limitation to the disclosure, and as will be described below, the conductive features 108 have critical dimensions (CDs) that are substantially smaller than the dimensions of conductive features that are provided in layers at or above the conductive features 108. It should be appreciated that the conductive features 108 shown in FIGS. 2A-2N are not drawn to scale and have critical dimensions that are relatively small in comparison. For example, the width (W1) of conductive feature 108 as shown in FIG. 2E can be substantially smaller in comparison to other features such as mask opening 147-1 of FIG. 2E. For instance, in one non-limiting example, the first mask openings 147-1, 147-2 illustrated in FIG. 2E can have widths (W2, W3) that range from about 25 to 30 nanometers and are thus substantially larger than the width (W1) of conductive feature 108 which can have a width that can range from about 5 to 20 nanometers (e.g., between 8 and 13 nanometers). The importance of this difference in dimensions between conductive features 108 and other features will be described in detail below.

As shown in FIGS. 2A, various material layers 103 are formed over material layers 102 in accordance with some embodiments. In particular, FIG. 2A illustrates an embodiment where the material layer 103 includes a first etch stop layer 110 formed over the dielectric layer 106, a second etch stop layer 112 formed over the first etch stop layer 110 and a dielectric layer 106 formed over the second etch stop layer 112. It should be appreciated that the material layer 103 in accordance with embodiments of the present disclosure is not limited to these layers, but rather, that the layers are shown to illustrate one non-limiting embodiment. For example, the material layer 103 may include more or less layers. For instance, in some other embodiments, the material layer 103 includes one or more additional layers positioned between the etch stop layer 110, the second etch stop layer 112, and the dielectric layer 114. In some other embodiments, the material layer 103 includes one or more additional layers positioned over the dielectric layer 114. In some other embodiments, the material layer 103 includes one or more additional layers positioned under the etch stop layer 110. In some other embodiments, the material layer 103 merely includes the etch stop layer 110 and the dielectric layer 114.

As shown in FIG. 2A, the first etch stop layer 110 may be formed over the dielectric layer 106, and a second etch stop layer 112 may be formed over the first etch stop layer 110. Depending on the implementation, the first and second etch stop layers 110, 112 may be formed from more than one layer. The first and second etch stop layers 110, 112 cover the conductive features 108 to protect the conductive features 108 from being damaged during subsequent etching processes. The first and second etch stop layers 110, 112 may serve as barrier layers that protect the dielectric layer 106 from diffusion of a metal material from subsequent conductive features during subsequent thermal processes or cycles.

In some embodiments, the thickness of the etch stop layer(s) can be in a range from about 10 Å to about 100 Å. In some embodiments, each of the etch stop layers can be made of or include plasma-enhanced oxide (PEOX), tetraethoxysilane (TEOS), aluminum nitride (AlN), aluminum oxide (AlOₓ), silicon carbide (SiC), silicon carbonitride (SiCN), silicon oxycarbide (SiCO), silicon nitride (SiN), silicon oxynitride (SiON), one or more other suitable materials, or a combination thereof. Examples of SiC include oxygen-doped silicon carbide (SiC:O, also known as ODC) and nitrogen-doped silicon carbide (SiC:N, also known as NDC). For instance, in one non-limiting embodiment, the first etch stop layer 110 may be made of or include a layer of aluminum oxide (AlOₓ), and the second etch stop layer 112 may be made of or include a layer of silicon oxide, silicon carbide (SiC), silicon oxycarbide (SiOC), a silicon oxycarbonitride (SiOCN), another suitable material, or a combination thereof.

In some embodiments, the etch stop layers 110, 112 can be formed by chemical vapor deposition (CVD), spin-on coating, another applicable process, or a combination thereof. The CVD process may include, but is not limited to, a low pressure CVD (LPCVD) process, a low-temperature CVD (LTCVD) process, a rapid thermal CVS (RTCVD) process, a plasma enhanced CVD (PECVD) process, a high density plasma CVD (HDPCVD) process, an atomic layer deposition (ALD) process, a plasma enhanced atomic layer deposition (PEALD) process, another applicable process, or a combination thereof.

As shown in FIG. 2A, in accordance with some embodiments, a dielectric layer 114 is deposited over the second etch stop layer 112. The dielectric layer 114 serves as an IMD layer of an interconnection structure. In some embodiments, the dielectric layer 114 is thicker than the dielectric layer 106, but embodiments of the disclosure are not limited thereto. For instance, in some embodiments, the thickness of the dielectric layer 106 is in a range from about 100 Å to about 300 Å, whereas the thickness of the dielectric layer 114 is in a range from about 200 Å to about 400 Å. Although FIG. 2A shows that the dielectric layer 114 as a single layer, embodiments of the disclosure are not limited thereto. In some other embodiments, the dielectric layer 114 is a multi-layer structure including dielectric sub-layers (not shown). The materials and/or formation methods of the dielectric layer 114 are the same as or similar to those of the dielectric layer 106, as illustrated in the aforementioned embodiments, and therefore are not repeated.

As shown in FIG. 2B, a hard mask 130 can then be formed over the dielectric layer 114. The hard mask 130 can include one or more layers of material. In accordance with the disclosed embodiments, the hard mask 130 includes at least one hard mask layer 134 comprised of a tungsten containing material or tungsten-based material, such as a tungsten carbide (WCₓ) layer or a tungsten nitride (WNₓ) layer. In more general terms, the hard mask layer 134 can be made of or include materials that when etched with an etchant gas result in relatively low boiling point etching by-products in comparison to other types of materials that are often used as hard mask layer, such as metal nitrides that may include, but are not limited to, titanium nitride, etc.

In the non-limiting example illustrated in FIG. 2B, the hard mask 130 is a mask stack that includes a first oxide layer 132 formed over the dielectric layer 114, the hard mask layer 134 formed over the first oxide layer 132, and a second oxide layer 136 formed over the hard mask layer 134. In some embodiments, the first oxide layer 132 can function as an anti-reflective coating layer.

The first oxide layer 132 can protect a dielectric layer 114 from diffusion of metal material during subsequent thermal processes or cycles. The hard mask layer 134 may then be deposited over the first oxide layer 132, and the second oxide layer 136 may then be deposited over the hard mask layer 134 to result in a structure or stack in which the hard mask layer 134 is longitudinally sandwiched between the oxide layers 132, 136.

In some non-limiting embodiments, the first oxide layer 132 and the second oxide layer 136 can be made of or include an oxide layer, silicon carbide (SiC) layer, silicon oxycarbide (SiOC) layer, silicon nitride (SiN) layer, one or more other suitable materials, or a combination thereof. In some embodiments, the first oxide layer 132 and the second oxide layer 136 can be deposited using a PVD process, a CVD process, an ALD process, one or more other applicable processes, or a combination thereof. In some embodiments, the second oxide layer 136 may have a thickness that is greater than the first oxide layer 132.

In some embodiments, the hard mask layer 134 is made of or includes a tungsten-based material. In some embodiments, the hard mask layer 134 may be made of or include a tungsten-based layer such as a tungsten (W) layer, a tungsten carbide (WCₓ) layer, a tungsten nitride (WNₓ) layer, a tungsten boride (WB) layer, a tungsten boron carbide (WBC) layer, a tungsten boron nitride (WBN) layer, a tungsten carbonitride (WCN) layer, or any combination thereof. Tungsten carbide (WCₓ) films, for example, can provide characteristics such as strong adhesion, stress and a high etch selectivity when implemented as a hard mask. In some embodiments, the hard mask layer 134 may be made of or include a tantalum nitride (TaN) layer, a molybdenum carbide (MoC) layer, or a Zirconium (Zr) layer, or any combination thereof. Although the hard mask layer 134 is illustrated as a single layer in FIG. 2B, in other embodiments, the hard mask layer 134 can be a multi-layer structure that includes multiple layers of materials in addition to a tungsten-based material as described above. The hard mask layer 134 can be formed by using an applicable deposition process, such as a PVD process, a plating process, a CVD process, a spin-on process, one or more other applicable processes, or a combination thereof.

As shown in FIG. 2C, steps are performed to form a first trench 138 in the hard mask 130. Although not illustrated in FIG. 2C, a photoresist layer (or other photo-sensitive layer capable of being patterned using a photolithography process) can be formed in and overlying the hard mask 130. Depending on the implementation, the photoresist layer can be a single layer of material, or a multi-layer structure including multiple sub-layers. The photoresist layer may be negative type or positive type. Although not shown in FIG. 2C, the photoresist layer can be patterned to form a patterned photoresist layer over the hard mask 130. The patterned photoresist layer defines a trench pattern that can be transferred into a portion of the hard mask 130. One or more etching processes can then be sequentially performed to remove exposed portions of the second oxide layer 136, the hard mask layer 134, and the first oxide layer 132, and, as shown in FIG. 2C, leave portions of the second oxide layer 136-1, the hard mask layer 134-1, and the first oxide layer 132-1 remaining to define the trench 138 in the hard mask 130. The hard mask layer 134 etches with a high selectivity with respect to the first and second oxide layers 132, 136.

After etching the first trench 138, a removal process can then be performed to remove the patterned photoresist layer (not illustrated) so that the patterned hard mask 130-1 remains over the dielectric layer 114 with the first trench 138 formed therein. As a result of the etching processes that are applied, the pattern of trench pattern 138 is transferred to the patterned hard mask 130-1. After processing in FIG. 2C is complete, portions of the patterned hard mask 130-1 that remain (e.g., the remaining portions of the second oxide layer 136-1, the hard mask layer 134-1, and the first oxide layer 132-1) form are mask elements that collectively define a first trench 138 having a pattern or profile that will subsequently be transferred into the dielectric layer 114.

As shown in FIG. 2D, a multi-layer resist layer 140 can then be formed in and over the patterned hard mask 130-1. The use of a multi-layer resist scheme can allow for via openings to be patterned that have large aspect ratio, while also providing improvements in line edge roughness (LER) and line width roughness (LWR), among other benefits. As shown in FIG. 2D, the multi-layer resist layer 140 has a multi-layer structure that includes multiple layers 142, 144, 146. In non-limiting embodiment shown in FIG. 2D, the multi-layer resist layer 140 is a tri-layer structure including a bottom layer 142 formed over the patterned hard mask 130-1, a middle layer 144 formed over the bottom layer 142, and an upper layer 146 formed over the middle layer 144. Although FIG. 2D shows that the multi-layer resist layer 140 includes three layers, it should be appreciated that embodiments of the disclosure are not limited thereto, and that in other embodiments, the multi-layer resist layer 140 can include fewer or more layers. As such, it is understood that in other embodiments, one or more layers of the tri-layer photoresist may be omitted, or additional layers may be provided as a part of the tri-layer photoresist, and the layers may be formed in difference sequences.

As will be explained in greater detail below, in some embodiments, the bottom layer 142 and the upper layer 146 are organic layers (e.g., made of or including an organic material), and the middle layer 144 is a silicon-containing layer. For instance, in some embodiments, the bottom layer 142 includes a CₓH_{y}O_{z} material, the middle layer 144 includes a SiCₓH_{y}O_{z} material, and the upper layer 146 includes a CₓH_{y}O_{z} material. The CₓH_{y}O_{z} material of the bottom layer 142 may be identical to the CₓH_{y}O_{z} material of the upper layer 146 in some embodiments, but they may also be different materials in other embodiments. The upper layer 146 may be a photo-sensitive layer (e.g., photoresist) capable of being patterned using a photolithography process. For example, the upper layer 146 also includes a photo-sensitive element, such as a photo-acid generator (PAG) that allows a photolithography process to be performed to pattern the upper layer 146. The upper layer 146 may be negative type or positive type.

As shown in FIG. 2D, the bottom layer 142 is deposited in and overlying the patterned hard mask 130-1 to fill the first trench 138 that is formed in the patterned hard mask 130-1. In some embodiments, the bottom layer 142 is an organic layer and is made of organic material. In some embodiments, the bottom layer 142 layer contains a material that is patternable. In some embodiments, the bottom layer 142 layer has a composition tuned to provide anti-reflection properties. In some embodiments, the bottom layer 142 includes photo-acid generator (PAG), thermal-acid generator (TAG), photo-base generator (PBG), thermal-base generator (TBG), and/or quencher. In some embodiments, the bottom layer 142 is deposited by a spin coating process. In some other embodiments, the bottom layer 142 is deposited by another applicable deposition process.

As shown in FIG. 2D, the middle layer 144 is deposited over the bottom layer 142, in accordance with some embodiments. In some embodiments, the middle layer 144 includes a silicon-containing layer (e.g., silicon hard mask material). In some embodiments, the middle layer 144 includes a silicon-containing inorganic polymer. In some embodiments, the middle layer 144 includes a siloxane polymer (e.g., a polymer having a backbone of O—Si—O—Si— etc.). The silicon ratio of the middle layer 144 material may be adjusted to control the etch rate. In some other embodiments the middle layer 144 includes silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials. In some embodiments, the middle layer 144 includes photo-acid generator (PAG), thermal-acid generator (TAG), photo-base generator (PBG), thermal-base generator (TBG), and/or quencher. In some embodiments, the middle layer 144 is deposited by a spin coating process. In some other embodiments, the middle layer 144 is deposited by another applicable deposition process.

As shown in FIG. 2D, the upper layer 146 is deposited over the middle layer 144, in accordance with some embodiments. In some embodiments, the upper layer 146 is a third, and top, layer of the multi-layer resist layer 140. In some embodiments, the upper layer 146 is an organic layer, a photoresist (PR) layer or a photosensitive layer, which is operable to be patterned by radiation. In some embodiments, the material of the upper layer 146 is the same as the material of the bottom layer 142. In some other embodiments, the material of the upper layer 146 is different from the material of the bottom layer 142. For instance, in some embodiments, the upper layer 146 is made of or includes polyimide, metal-containing organic-inorganic hybrid compound, one or more other suitable materials, or a combination thereof. Examples of the metal-containing organic-inorganic hybrid compound may include metal-containing oxide (such as ZrOₓ or TiOₓ) or another organic-inorganic hybrid compound.

In some embodiments, the chemical properties of the portion of the upper layer 146 struck by incident radiation changes in a manner that depends on the type of photoresist used. In some embodiments, the upper layer 146 is a suitable positive tone resist. Positive tone resist refers to a photoresist material that when exposed to radiation (typically UV light) becomes insoluble to a negative tone developer, while the portion of the photoresist that is not exposed (or exposed less) is soluble in the negative tone developer. In some embodiments, the term “negative tone developer” refers to any suitable developer that selectively dissolves and removes areas that received no exposure dose or an exposure dose below a predetermined threshold exposure dose value. In some embodiments, the negative tone developer includes an organic solvent (e.g., a ketone-based solvent, ester-based solvent, alcohol-based solvent, amide-based solvent, ether-based solvent, hydrocarbon-based solvent, and/or other suitable solvent).

In some embodiments, the upper layer 146 includes a carbon backbone polymer. In some embodiments, the upper layer 146 includes other suitable components such as a solvent and/or photo acid generators. In some embodiments, the upper layer 146 is a chemical amplified (CA) resist. In some embodiments, the photoresist layer includes a photo-acid generator (PAG) distributed in the photoresist layer. In some embodiments, when absorbing photo energy from an exposure process, the PAG forms a small amount of acid. In some embodiments, the resist includes a polymer material that varies its solubility to a developer when the polymer is reacted with this generated acid. In some embodiments, the chemical amplified resist is a positive tone resist.

In some embodiments, the upper layer 146 is deposited by a spin coating process. In some other embodiments, the upper layer 146 is deposited by another applicable deposition process.

In some embodiments, the thicknesses of the bottom layer 142, the middle layer 144 and the upper layer 146 are different from each other. In some embodiments, the thickness of the bottom layer 142 is in a range from about 200 nm to about 400 nm. In some embodiments, the thickness of the middle layer 144 is in a range from about 20 nm to about 40 nm. In some embodiments, the thickness of the upper layer 146 is in a range from about 80 nm to about 200 nm.

As shown in FIG. 2E, the upper layer 146 is developed and can be patterned to form a patterned upper layer 146-1 (or photoresist mask) with one or more first mask openings 147-1, 147-2. In some embodiments, the upper layer 146 is exposed to a radiation beam. In some embodiments, the radiation beam exposes the upper layer 146 using a lithography system that provides a pattern of the radiation according to an IC design layout. In some embodiments, a lithography system employs an extreme ultraviolet (EUV) photolithography process to expose the upper layer 146 to extreme ultraviolet (EUV) radiation. The EUV photolithography process, may include one or more exposures, as well as developing, rinsing, and baking processes (not necessarily performed in this order).

For example, after the exposed upper layer 146 is exposed, a developer is applied to the exposed upper layer 146 to form the patterned upper layer 146-1. In some embodiments, a negative tone developer is applied to the exposed upper layer 146. The term “negative tone developer” refers to a developer that selectively dissolves and removes areas that received no exposure dose or an exposure dose below a predetermined threshold exposure dose value. In some embodiments, the developer includes an organic solvent or a mixture of organic solvents, such as methyl a-amyl ketone (MAK) or a mixture involving the MAK. In some other embodiments, a developer includes a water based developer, such as tetramethylammonium hydroxide (TMAH). In some embodiments, applying a developer includes spraying a developer on the exposed resist film, for example by a spin-on process. In some embodiments, the developer removes the non-exposed regions of the resist leaving the portions that have been exposed. In some embodiments, after development, one or more additional etching processes may be performed.

To simplify the drawings, only two first mask openings 147-1, 147-2 are depicted in the patterned upper layer 146-1. The first mask openings 147-1, 147-2 expose portions of the underlying middle layer 144. The region of the patterned upper layer 146-1 that is between the first mask openings 147-1, 147-2 serves as an isolation feature. The first mask openings 147-1, 147-2 that are defined in the patterned upper layer 146-1 are eventually used define a pattern for second mask openings 148-1, 148-2 that will subsequently be formed in and through the middle layer 144 and the bottom layer 142. As mentioned above, due to the nature of the EUV lithography process used to pattern the upper layer 146, the first mask openings 147-1, 147-2 are formed in the patterned upper layer 146-1 can have different dimensions. For instance, as one non-limiting example, the widths (W2, W3) could be different for each of the first mask openings 147-1, 147-2 due to non-uniformity associated with EUV photolithography.

An etching process is performed using the patterned upper layer 146-1 (of FIG. 2E) as an etch mask to etch the middle layer 144 and remove the exposed portions of the middle layer 144 and form a patterned middle layer 144-1 (FIG. 2F). As shown in FIG. 2F, the portions of the middle layer 144 not covered by the patterned upper layer 146-1 are etched to form the patterned middle layer 144-1. The patterned middle layer 144-1 includes the second mask openings 148-1, 148-2 that expose portions of the bottom layer 142. As shown in FIG. 2F, the second mask openings 148-1, 148-2 are aligned with the first mask openings 147-1, 147-2 (of FIG. 2E). In some embodiments, the pattern of the patterned upper layer 146-1 with the first mask openings 147-1, 147-2 is transferred to the patterned middle layer 144-1 through the etching process. Therefore, in some embodiments, after the etching process, the patterned middle layer 144-1 with the second mask opening 148-1, 148-2 has same pattern as the patterned upper layer 146-1.

In some embodiments, the etching process used to remove the exposed portions of the middle layer 144 is a dry etch process. In some embodiments, the dry etch process uses oxygen plasma, carbon dioxide plasma, another suitable plasma, or a combination thereof. In some other embodiments, the etching process that is applied to remove exposed material of the middle layer 144 (i.e., that is not covered by the patterned upper layer 146-1) is a dry etching process using etchant(s) including CF₄, C₃F₈, C₄F₈, CHF₃, and/or CH₂F₂. In some embodiments, the etching process is a reactive ion etching process, a plasma etching process, any other applicable etching process, or a combination thereof. During the etching process, or as part of a separate removal process, the patterned upper layer 146-1 may also be removed.

Another etching process is performed using the patterned middle layer 144-1 (of FIG. 2F) as an etch mask to etch the bottom layer 142 and remove the exposed portions of the bottom layer 142 to form a patterned bottom layer 142-1, as shown in FIG. 2G. For example, the exposed portions of the bottom layer 142 (that are not covered by the patterned middle layer 144-1) are etched through the second mask openings 148-1, 148-2 to form the patterned bottom layer 142-1 (as shown in FIG. 2G). The patterned bottom layer 142-1 includes third mask openings 148-1′, 148-2′ that are separated by an isolation feature positioned between the third mask openings 148-1′, 148-2′. The third mask openings 148-1′, 148-2′ expose portions of first oxide layer 132-1. In some embodiments, the pattern of the patterned middle layer 144-1 is transferred to the patterned bottom layer 142-1 through the etching process, such that the third mask openings 148-1′, 148-2′ are aligned with the second mask openings 148-1, 148-2. In some embodiments, the etching process used to etch the bottom layer 142 is a dry etch process. In some embodiments, the dry etch process uses oxygen plasma, carbon dioxide plasma, another suitable plasma, or a combination thereof. In some embodiments, the etching process is a reactive ion etching process, a plasma etching process, any other applicable etching process, or a combination thereof. During the etching process, or as part of a separate removal process, the patterned middle layer 144-1 may also be removed.

As shown in FIG. 2H, an etching process is performed using the patterned bottom layer 142-1 as an etch mask to etch and remove exposed portions of the first oxide layer 132-1 and underlying portions of the dielectric layer 114 to thereby extend the third mask openings 148-1′, 148-2′ into the dielectric layer 114 and form first via openings 149-1, 149-2. In some embodiments, parameters of the etching process are controlled such that the first via openings 149-1, 149-2 extend partially into, but not through the dielectric layer 114. As shown in FIG. 2H, the portions of the first oxide layer 132-1 not covered by the patterned bottom layer 142-1 are etched to expose underlying portions of the dielectric layer 114 and the etching process continues to a controlled depth into the dielectric layer 114. As a result, the etching process forms a patterned first oxide layer 132-1 and a patterned dielectric layer 114-1. As shown in FIG. 2H, the first via openings 149-1, 149-2 are aligned with the third mask openings 148-1′, 148-2′, and separated by an isolation feature positioned between the first via openings 149-1, 149-2. In some embodiments, the etching process is a dry etch process. In some embodiments, the dry etch process uses oxygen plasma, carbon dioxide plasma, another suitable plasma, or a combination thereof. In some other embodiments, the etching process is a reactive ion etching process, a plasma etching process, any other applicable etching process, or a combination thereof. In some embodiments, during the etching process, or as part of a separate removal process, the patterned bottom layer 142-1 may also be removed.

As shown in FIG. 2I, a removal process can be performed to remove the remaining portions of the patterned bottom layer 142-1. In some embodiments, the patterned bottom layer 142-1 can be removed by using an ashing process or stripping process. In some embodiments, the ashing process uses oxygen plasma, carbon dioxide plasma, another suitable plasma, or a combination thereof. As shown in FIG. 2I, the remaining mask elements of the patterned hard mask 130-1, which include the remaining portions 138-1 of the first trench 138 (of FIG. 2I), form an etch mask structure that serve as an etch mask during subsequent etching steps.

As shown in FIG. 2J, another dry etching process can then be performed with the remaining mask elements of the patterned hard mask 130-1 serving as an etch mask. In this dry etching process, the remaining portions 138-1 of the first trench 138 (of FIG. 2I) can be further extended into the dielectric layer 114. This dry etching process also removes at least some portions of the remaining mask elements of the patterned hard mask 130-1. For example, in some embodiments, as illustrated in FIG. 2J, this dry etching process also removes the remaining portions 136-1 of the second oxide layer 136, and partially etches the remaining portions 134-1 of hard mask layer 134 and portions of the first oxide layer 132 (e.g., so that they have a concave profile). The dry etching process also partially etches portions of the dielectric layer 114 that underlie the trench 138-1 to form a trench 160 that extends deeper into the patterned dielectric layer 114-1. As also shown, this dry etching process also removes portions of the second etch stop layer 112 that underlie the first via openings 149-1, 149-2 (shown in FIG. 2I) so that second via openings 150-1, 150-2 extend through the second etch stop layer 112 and to the first etch stop layer 110, where the etching process stops. In this regard, the dry etching process used in FIG. 2J to extend the trench 160 into the dielectric layer 114 and to extend the second via openings 150-1, 150-2 to the first etch stop layer 110 may also include a wet etching process in some embodiments.

As shown in FIG. 2K, a wet etching process can then be performed to remove exposed portions of the first etch stop layer 110 so that the third via openings 152-1, 152-2 extend through the first etch stop layer 110 to the conductive features 108. In other words, the portions of the first etch stop layer 110 exposed by the third via openings 152-1, 152-2 are etched so that the third via openings 152-1, 152-2 extend through the etch stop layer 110 and expose a surface of the conductive features 108. In other embodiments, a dry etching process can be applied in combination with the wet etching process.

As shown in FIG. 2L, a barrier layer 188 can then be conformally deposited so that it over the remaining portions of the dielectric layer 114 and the third via openings 152-1, 152-2. The barrier layer 188 conformally covers the top surface of the material layer 102, the sidewalls of the material layer 102 exposed by the trench 160 and the third openings 152-1, 152-2. In some embodiments, the barrier layer 188 is made of a metal nitride such as TaN, TiN, WN, TbN, VN, ZrN, CrN, WC, WN, WCN, NbN, MN, and combinations thereof. In some embodiments, the barrier layer 188 includes a Ta/TaN bi-layer structure. In some embodiments, the barrier layer 188 is deposited by using physical vapor deposition (PVD), chemical vapor deposition (CVD), plasma enhanced chemical vapor deposition (PECVD), or plasma enhanced atomic layer deposition (PEALD), other applicable processes, or a combination thereof.

As shown in FIG. 2M, a conductive layer 190 can then be deposited over the diffusion barrier layer 188 to fill the second trench 160 and third via openings 152-1, 152-2. The conductive layer 190 may include a seed layer, which is not shown in figures for the purpose of simplicity and clarity. The barrier layer 188 is positioned between the conductive layer 190 and other parts of the material layer 102 and/or the semiconductor substrate 101 so as to prevent metal diffusion from the conductive layer 190 into the material layer 102 and/or the semiconductor substrate 101. In some embodiments, the conductive layer 190 is made of or includes copper, aluminum, tungsten, titanium, cobalt, tantalum, gold, chromium, nickel, platinum, iridium, rhodium, an alloy thereof, another conductive material, or a combination thereof. In some embodiments, the conductive layer 190 is deposited using an electroplating process, a PVD process, a CVD process, an electroless plating process, one or more other applicable processes, or a combination thereof.

As shown in FIG. 2N, a planarization process can be performed to remove portions of the conductive layer 190 overlying and outside of the second trench 160, portions of the diffusion barrier layer 188, and the remaining portions 134-2 of the hard mask layer 134 and remaining portions 132-2 of the oxide layer 132 until portions of the dielectric layer 114 are exposed. The planarization process may include a chemical mechanical polishing (CMP) process, a dry polishing process, a grinding process, an etching process, one or more other applicable processes, or a combination thereof.

Following the planarization process, conductive features 190, 192-1, 192-2 are confined in remaining portions of the dielectric layer 114. The remaining portions of the conductive layer 190 form conductive features 190, 192-1, 192-2 of interconnect structure 195. Conductive feature 190 is electrically connected to the conductive features 108 through the conductive features 192-1, 192-2. The conductive feature 190 that remains in the trench 160 may form a structure that is referred to as a conductive interconnect line, and the conductive features 192-1, 192-2 that contact conductive features 108 may be referred to as conductive vias. The conductive features 192-1, 192-2 may have substantially the same width or different widths. For example, one of the conductive features 192-1 may be wider than the other conductive feature 192-2.

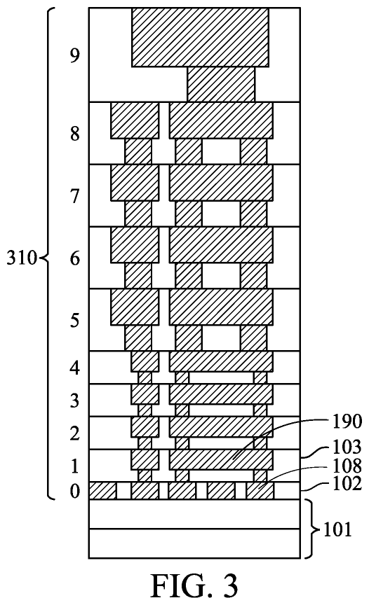

Following fabrication of the interconnect structure 195 illustrated in FIG. 2N, one or more dielectric layers and multiple conductive features may be formed over the dielectric layer 114 and the conductive features 190, 192-1, 192-2 to continue the formation of the interconnection structure of the semiconductor device structure, as shown in one non-limiting example that will be described with reference to FIG. 3.

FIG. 3 is a cross-sectional view that illustrates different back-end-of-line interconnect layers 310 of an integrated circuit architecture 300 where interconnect structures fabricated in accordance with FIGS. 1 and 2A-2N may be integrated in accordance with some embodiments. As shown in FIG. 3, conductive features 108 of FIG. 2N may be part of a metal zero (M0) layer 102, and the conductive features 190, 192-1, 192-2 may be, for example, part of a metal one (M1) interconnect layer. In some embodiments, the steps illustrated in FIGS. 2A-2N are repeated one or more times to continue the formation of additional interconnection structures in a metal two (M2) interconnect layer or higher. For example, one or more etch stop layers, which may be the same as or similar to the first etch stop layer 110 and second etch stop layer 112, may be deposited to cover the dielectric layer 114 shown in FIG. 2N and the interconnect structure 195. Afterwards, the same or similar steps as those described in FIGS. 2A-2N are performed over the upper etch stop layer (not illustrated) to produce interconnect structures similar to that illustrated in FIG. 2N in a metal two (M2) layer. The same or similar steps as those described in FIGS. 2A-2N can then be repeated again to produce interconnect structures similar to those illustrated in FIG. 2N in other metal layers, which are shown as interconnect layers 3 through 9 in FIG. 3 for illustrative purposes, but are not limited to interconnect layers 3 through 9. In other implementations, additional interconnect layers could be provided.

The steps described in FIGS. 2A-2N describe what is commonly referred to as a via-first dual damascene process for fabricating an interconnect structure, but are not necessarily limited to being used in a via-first dual damascene process. For instance, the embodiments of the disclosure may also be applied to a single damascene process for fabricating the interconnect structure.

As explained above, the conductive features 108 formed in material layer 102 have very small critical dimensions. When fabricating interconnect structures having vias that need to contact these conductive features 108, the small critical dimensions of the conductive features 108 can make it very challenging to form via openings that extend through the dielectric layer 114 to the conductive features 108. One approach for doing so is to use advanced EUV lithography technologies that involve multiple patterning steps so that the via openings can be opened through the dielectric layer 114 and reach the conductive features. These multiple patterning steps typically involve multiple mask layers and etching steps to pattern via openings. A hard mask is usually formed over the dielectric layer 114 to prevent damage to the dielectric layer 114.

As explained above, when a metal nitride hard mask (e.g., TiN hard mask or the like) is used etching by-products are generated due to reactions between etchants gas and the hard mask material that is being etched. It has been observed that these etching by-products can be deposited and accumulate on surfaces of the dielectric layer 114 during subsequent etching process in the small and narrow via openings and/or along the trench. As the critical dimensions of the via openings get smaller during the process of forming the via openings, this can cause under etching problems to occur during subsequent etching steps. This is because the fluorinated etching by-products have relatively high-boiling points (e.g., relatively low volatility), which, as explained above, can cause an under etching problem to occur during the process of forming the via openings.

To explain further, when etching a dielectric material, a carbonfluoro-containing etching gas (e.g., CF₄, C₄F₈, etc.) is usually applied, and the reaction between this etching gas and the hard mask material can result in etching by products being generated. For example, when a TiN hardmask is used, a titanium fluoride (TiFₓ) by-product is generated. The titanium fluoride (TiFₓ) by-product is metallic and has relatively high boiling point that causes it to accumulate in and block the via openings, which in turn, can result in under-etching of the via openings. This is especially true as the critical dimensions of the vias, and hence the via openings shrink and get smaller because the titanium fluoride (TiFₓ) by-products fill up more of the via openings due to the fact that these by-products have a relatively high boiling point. As a result of this blockage, under-etching of the via openings can occur.

If under etching is left unaddressed, the vias that are eventually formed in the under etched via openings have degraded electrical contact with the conductive feature that they contact. For example, in some cases, this can result in a via that exhibits poor quality of contact with the conductive feature (e.g., a via that has poor performance). In an extreme case, this can result in a via that does not contact the conductive feature at all (e.g., a via that is inoperable). In either case, if under etching is not addressed, the quality of the via is negatively impacted.

In accordance with the disclosed embodiments, a hard mask that is formed over the dielectric layer 114 can include a tungsten-based material or layer. This can be advantageous in comparison to using other conventional types of hard masks, such as, metal nitride hard masks, because etching by-products, that are generated during various etching steps, have a lower boiling point and do not tend to block the via openings that are being etched. To explain further, when a hard mask that comprises a tungsten-based material is used, tungsten fluoride (WFₓ) etching by-products are produced that have a lower boiling point than the etching by-products produced when another material, like titanium nitride (TiN), is used as the hard mask. Due to lower boiling point of tungsten fluoride, the etching by-products do not tend to accumulate in the via openings. As a result, under etching problems can be greatly reduced or eliminated.

For example, this can greatly reduce or prevent under etching issues that may otherwise occur during subsequent etching steps (e.g., when attempting to open the first via openings 149-1, 149-2 so that they extend to the second etch stop layer 112). Because under etching issues are reduced or eliminated, the resulting second via openings 150-1, 150-2 (shown in FIG. 2J) are improved, which in turn, improves the third via openings 152-1, 152-2 (FIG. 2K) that are formed to reach the underlying conductive features 108. This is particularly beneficial in cases where the mask openings, via openings, and conductive features 108 have small dimensions (e.g., widths between 5 to 20 nanometers such as widths between 8 and 13 nanometers).

One option for addressing under etching would be to perform additional etching steps, but this would add complexity to the fabrication sequence in order to extend via opening to reach the conductive feature. In addition, additional etch stop layers would be required, which would add even more complexity to the overall fabrication sequence. As such, another advantage of the disclosed embodiments is that because under etching is no longer a concern, the number of etching steps that are needed can be reduced. As such, the number of etch stop layers that are needed can be reduced in comparison to other approaches where under etching is a concern, which can further simplify the over fabrication sequence used to form the interconnect.

In some embodiments, methods are provided for forming a semiconductor device structure. In accordance with these methods, a first etch stop layer is formed overlying a semiconductor structure having a conductive feature formed therein, and a second etch stop layer is formed overlying the first etch stop layer. A dielectric layer is formed overlying the second etch stop layer. A hard mask, that comprises a tungsten-based material, is formed overlying the dielectric layer, and patterned to create a patterned hard mask. In some embodiments, the tungsten-based material comprises tungsten carbide. In some embodiments, the tungsten-based material comprises tungsten nitride.

A resist layer is formed over the patterned hard mask, and patterned to form a patterned resist layer. Using the patterned resist layer as a mask, a first etching process is performed to form a via opening that extends partially through the dielectric layer. Using the patterned hard mask as an etch mask, a second etching process is performed to extend the via opening through the second etch stop layer, and a third etching process can be performed to extend the via opening through the first etch stop layer to reach the conductive feature. In some embodiments, the second etching process is a dry etching process, and the third etching process is a wet etching process. In some embodiments, the method further includes filling the via opening with a conductive material to form a via in the dielectric layer.

In some embodiments, the resist layer comprises a multi-layer resist layer that comprises an upper layer, a middle layer, and a bottom layer. In some embodiments, the resist layer can be patterned to form the patterned resist layer by performing a first set of etching processes to form a patterned bottom layer. In some embodiments, the first etching process uses the patterned bottom layer as a mask to form the via opening that extends partially through the dielectric layer.

In some embodiments, the patterning of the hard mask includes patterning a trench in the hard mask to create the patterned hard mask. In some embodiments, the second etching process uses the patterned hard mask as an etch mask to extend the trench further into the dielectric layer and to extend the via opening through the second etch stop layer.

In some embodiments, other methods are provided for forming a semiconductor device structure. In accordance with these methods, a first etch stop layer is formed overlying a semiconductor structure having a conductive feature formed therein, and a second etch stop layer is formed overlying the first etch stop layer. A dielectric layer is formed overlying the second etch stop layer. A hard mask, that comprises a tungsten-based material, is formed overlying the dielectric layer, and patterned to create a patterned hard mask. In some embodiments, the tungsten-based material comprises tungsten carbide. In some embodiments, the tungsten-based material comprises tungsten nitride.

A multi-layer resist layer, that includes a bottom layer, is formed over the patterned hard mask, and a first set of etching processes are performed to pattern the multi-layer resist layer to create a patterned bottom layer. A first etching process is performed, using the patterned bottom layer as a mask, to form a via opening that extends partially through the dielectric layer. A second etching process is performed, using the patterned hard mask as an etch mask, to extend the via opening through the second etch stop layer, and a third etching process is performed to extend the via opening through the first etch stop layer to reach the conductive feature. In some embodiments, the method further includes filling the via opening with a conductive material to form a via in the dielectric layer that electrically contacts the conductive feature.

In some embodiments, the patterning of the hard mask includes patterning a trench in the hard mask to create the patterned hard mask.

In some embodiments, the second etching process is performed, using the patterned hard mask as an etch mask, to extend the trench further into the dielectric layer and to extend the via opening through the second etch stop layer. In some embodiments, the second etching process is a dry etching process and the third etching process is a wet etching process.

In some embodiments, other methods are provided for forming a semiconductor device structure. In accordance with these methods, a semiconductor structure is provided having at least one conductive feature formed therein. A first etch stop layer is formed overlying a semiconductor structure having a conductive feature formed therein, and a second etch stop layer is formed overlying the first etch stop layer. A dielectric layer is formed overlying the second etch stop layer.

An interconnect structure is formed in the dielectric layer. The interconnect structure can be formed by forming a hard mask overlying the dielectric layer, wherein the hard mask comprises a tungsten-based material; patterning a trench in the hard mask to create a patterned hard mask; forming a multi-layer resist layer over the patterned hard mask, wherein the multi-layer resist layer comprises an upper layer, a middle layer, and a bottom layer; performing a first set of etching processes to pattern the multi-layer resist layer to form a patterned bottom layer; performing another etching process a second set of etching processes, using the patterned bottom layer as a mask, to form a via opening that extends partially through the dielectric layer; performing a dry etching process, using the patterned hard mask as an etch mask, to extend the trench further into the dielectric layer and to extend the via opening through the second etch stop layer; performing a wet etching process to extend the via opening through the first etch stop layer to reach the conductive feature; and filling the via opening and the trench with a conductive material to form the interconnect structure in the dielectric layer, wherein the interconnect structure electrically contacts the conductive feature. In some embodiments, the tungsten-based material comprises tungsten carbide. In some embodiments, the tungsten-based material comprises tungsten nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, the method comprising:
forming a first etch stop layer overlying a semiconductor structure having a conductive feature formed therein;
forming a second etch stop layer overlying the first etch stop layer;
forming a dielectric layer overlying the second etch stop layer;
forming a hard mask overlying the dielectric layer, wherein the hard mask comprises a tungsten-based material;
patterning the hard mask to create a patterned hard mask;
forming a resist layer over the patterned hard mask;
patterning the resist layer to form a patterned resist layer;
performing a first etching process, using the patterned resist layer as a mask, to form a via opening that extends partially through the dielectric layer;
performing a second etching process, using the patterned hard mask as an etch mask, to extend the via opening through the second etch stop layer; and
performing a third etching process to extend the via opening through the first etch stop layer to reach the conductive feature.

2. The method as claimed in claim 1, wherein the tungsten-based material comprises tungsten carbide.

3. The method as claimed in claim 1, wherein the tungsten-based material comprises tungsten nitride.

4. The method as claimed in claim 1, wherein forming a resist layer, comprises:
forming a multi-layer resist layer over the patterned hard mask, wherein the multi-layer resist layer comprises an upper layer, a middle layer, and a bottom layer.

5. The method as claimed in claim 4, wherein patterning the resist layer to form a patterned resist layer comprises:
performing a first set of etching processes to pattern the multi-layer resist layer to form a patterned bottom layer.

6. The method as claimed in claim 5, wherein performing the first etching process to form the via opening that extends partially through the dielectric layer, comprises:
performing the first etching process, using the patterned bottom layer as a mask, to form the via opening that extends partially through the dielectric layer.

7. The method as claimed in claim 1, wherein patterning the hard mask to create a patterned hard mask, comprises:
patterning a trench in the hard mask to create the patterned hard mask.

8. The method as claimed in claim 7, wherein performing the second etching process, comprises:
performing the second etching process, using the patterned hard mask as an etch mask, to extend the trench further into the dielectric layer and to extend the via opening through the second etch stop layer.

9. The method as claimed in claim 8, wherein the second etching process is a dry etching process and wherein the third etching process is a wet etching process.

10. The method as claimed in claim 1, further comprising:
filling the via opening with a conductive material to form a via in the dielectric layer.

11. A method for forming a semiconductor device structure, the method comprising:
forming a first etch stop layer overlying a semiconductor structure having a conductive feature formed therein;
forming a second etch stop layer overlying the first etch stop layer;
forming a dielectric layer overlying the second etch stop layer;
forming a hard mask overlying the dielectric layer, wherein the hard mask comprises a tungsten-based material;
patterning the hard mask to create a patterned hard mask;
forming a multi-layer resist layer over the patterned hard mask, the multi-layer resist layer comprising a bottom layer;
performing a first set of etching processes to pattern the multi-layer resist layer to create a patterned bottom layer;
performing a first etching process, using the patterned bottom layer as a mask, to form a via opening that extends partially through the dielectric layer;
performing a second etching process, using the patterned hard mask as an etch mask, to extend the via opening through the second etch stop layer; and
performing a third etching process to extend the via opening through the first etch stop layer to reach the conductive feature.

12. The method as claimed in claim 11, wherein the tungsten-based material comprises tungsten carbide.

13. The method as claimed in claim 11, wherein the tungsten-based material comprises tungsten nitride.

14. The method as claimed in claim 11, wherein patterning the hard mask to create a patterned hard mask, comprises:
patterning a trench in the hard mask to create the patterned hard mask.

15. The method as claimed in claim 14, wherein performing the second etching process, comprises:
performing the second etching process, using the patterned hard mask as an etch mask, to extend the trench further into the dielectric layer and to extend the via opening through the second etch stop layer.

16. The method as claimed in claim 15, wherein the second etching process is a dry etching process and wherein the third etching process is a wet etching process.

17. The method as claimed in claim 11, further comprising:
filling the via opening with a conductive material to form a via in the dielectric layer that electrically contacts the conductive feature.

18. A method for forming a semiconductor device structure, the method comprising:
providing a semiconductor structure having at least one conductive feature formed therein;
forming a first etch stop layer overlying the semiconductor structure;
forming a second etch stop layer overlying the first etch stop layer;
forming a dielectric layer overlying the second etch stop layer; and
forming an interconnect structure in the dielectric layer, wherein forming the interconnect structure comprises:
forming a hard mask overlying the dielectric layer, wherein the hard mask comprises a tungsten-based material;
patterning a trench in the hard mask to create a patterned hard mask;
forming a multi-layer resist layer over the patterned hard mask, wherein the multi-layer resist layer comprises an upper layer, a middle layer, and a bottom layer;
performing a first set of etching processes to pattern the multi-layer resist layer to form a patterned bottom layer;
performing another etching process, using the patterned bottom layer as a mask, to form a via opening that extends partially through the dielectric layer;
performing a dry etching process, using the patterned hard mask as an etch mask, to extend the trench further into the dielectric layer and to extend the via opening through the second etch stop layer;
performing a wet etching process to extend the via opening through the first etch stop layer to reach the conductive feature; and
filling the via opening and the trench with a conductive material to form the interconnect structure in the dielectric layer, wherein the interconnect structure electrically contacts the conductive feature.

19. The method as claimed in claim 18, wherein the tungsten-based material comprises tungsten carbide.

20. The method as claimed in claim 18, wherein the tungsten-based material comprises tungsten nitride.
